(19) United States
(12) Patent Application Publication
(10) Pub. No.: US 2024/0248153 A1
(43) Pub. Date: Jul. 25, 2024

(54) DETECTION UNIT FOR MAGNETIC SENSOR

(71) Applicant: Endress+Hauser SE+Co. KG, Maulburg (DE)

(72) Inventors: Dietmar Frühauf, Lörrach (DE); Raphael Kuhnen, Schliengen (DE)

(21) Appl. No.: 18/561,558

(22) PCT Filed: Apr. 20, 2022
(86) PCT No.: PCT/EP2022/060381

§ 371 Date: Nov. 16, 2023

(30) Foreign Application Priority Data
May 20, 2021 (DE) 10 2021 113 195.2

(51) Int. Cl. G01R 33/032

(52) U.S. Cl. CPC G01R 33/032

(57) ABSTRACT

A detection device for a magnetic sensor for detecting a magnetic field by means of a crystal body having at least one defect comprises a light source for exciting the defect; an excitation unit for producing a first excitation signal having a first specifiable frequency and a second excitation signal having a second specifiable frequency; a detector of a magnetic-field-dependent fluorescence signal of the crystal body; and an evaluation unit designed to determine the first excitation frequency and the second excitation frequency of the first and second excitation signals on the basis of the fluorescence signal such that the fluorescence signal as a function of the frequency has a minimum at the first excitation frequency and/or at the second excitation frequency Also disclosed is a magnetic sensor, a sensor device, and a method for detecting a magnetic field.

In industrial process automation, a wide variety of field devices are used for monitoring and/or determining at least one—for example, chemical or physical—process variable of a medium in a wide variety of embodiments. Therefore, within the framework of the present application, all measuring devices that are used in proximity to the process and that supply or process the process-relevant information are in principle termed field devices, therefore including also remote I/O's, wireless adapters, and general electronic components which are arranged at the field level. The companies of the Endress+Hauser Group produce and distribute a large variety of such field devices.

Many field devices are based upon the measurement of magnetic fields and the identification and/or ascertainment of the respective process variable and/or characteristic variable on the basis of a variable related to the respective magnetic field. Different types of magnetic field sensors are generally used to detect the magnetic field. The accuracy of such field devices is largely dependent upon the measurement accuracy of the magnetic field sensors. It would thus be desirable to be able to detect a magnetic field as precisely as possible in the simplest possible manner.

A newer development in the field of sensor technology is represented by so-called quantum sensors, in which a wide variety of quantum effects are utilized for determining various physical and/or chemical measured variables. In the field of industrial process automation, such approaches are of interest in particular with regard to increasing efforts towards miniaturization, while at the same time increasing the performance of the respective sensors.

Quantum sensors are based upon the fact that certain quantum states of individual atoms can be controlled and read very precisely. In this way, for example, precise and low-interference measurements of electrical and/or magnetic fields as well as gravitational fields with resolutions in the nanometer range are possible. For example, various spin-based sensor arrangements and systems based upon quantum-optical effects, such as quantum gravimeters, NMR gyroscopes, or optically-pumped magnetometers, are known, wherein the latter are based in particular upon gas cells.

In the case of spin-based quantum sensors, atomic transitions, e.g., in different crystal bodies, are utilized in order to detect even minor changes of movements, electrical and/or magnetic fields, or else gravitational fields. Typically, diamond with at least one silicon or nitrogen defect center, silicon carbide with at least one silicon defect, or hexagonal boron nitride with at least one defect color center is used as crystal body. The crystal bodies can in principle have one or more vacancies. Spin-based quantum sensors allow, for example, highly precise determination of magnetic fields.

For example, DE 3742878 A1 describes an optical magnetic sensor in which a crystal is used as a magnet-sensitive optical component.

Various further spin-based sensors have become known, for example, from the documents DE 10 2017 205 099 A1, DE 10 2017 205 265 A1, DE 10 2014 219 550 A1, DE 10 2018 214 617 A1, DE 10 2016 210 259 A1, and from the heretofore unpublished German patent applications with the file numbers 10 2020 123 993.9 and 10 2021 100223.0.

A spin-based sensor arrangement having a crystal body having at least one defect typically comprises an excitation unit for optical excitation of the defect, a detector for detecting a magnetic-field-dependent fluorescence signal from the crystal body, and, where applicable, a unit for producing high-frequency radiation or microwave radiation in the region of the crystal body. The magnetic field can then be optically detected on the basis of the magnetic electron spin resonances of the spin triplet of the ground state of the defect in the crystal body (ODMR, optically-detected magnetic resonance). The fluorescence signal has two characteristic minima corresponding to a frequency of the high-frequency radiation or microwave radiation, and thus the energetic position of the electron spin resonances. In order to be able to detect the magnetic field precisely, a detection of the minima in the fluorescence signal is, correspondingly, necessary. This is typically achieved by successively running through different frequencies and recording the fluorescence signal as a function of the frequency. However, this is a comparatively complex detection method. Frequency modulation of the high-frequency or microwave radiation together with a lock-in is also known. For example, the frequency is ascertained which brings about the greatest steepness of an edge of the amplitude of the fluorescence signal.

Proceeding from this, the object of the present invention is to provide a possibility for simplified and improved detection of the fluorescence signal for spin-based quantum sensors.

This object is achieved by the detection device according to claim 1, by the magnetic sensor according to claim 12, by the sensor device according to claim 13, and by the method according to claim 15.

With regard to the detection device, the object of the invention is achieved by a detection device for a magnetic sensor for detecting a magnetic field by means of a crystal body having at least one defect, comprising:
a light source for optical excitation of the defect in the crystal body by means of an excitation light,
an excitation unit for producing high-frequency radiation or microwave radiation in the region of the crystal body, which excitation unit is designed to produce a first excitation signal having at least one first specifiable excitation frequency and a second excitation signal having a second specifiable excitation frequency,
a detector for detecting a magnetic-field-dependent fluorescence signal from the crystal body, and
an evaluation unit which is designed for
   determining the first excitation frequency and/or the second excitation frequency of the first excitation signal and/or the second excitation signal on the basis of the fluorescence signal such that the fluorescence signal as a function of the frequency has a minimum at the first excitation frequency and/or at the second excitation frequency, and
   ascertaining a statement about the magnetic field on the basis of the first excitation frequency and/or the second excitation frequency.

According to the invention, the first excitation frequency and/or the second excitation frequency of the first excitation signal and/or the second excitation signal is thus determined in parallel, and in particular simultaneously, on the basis of the fluorescence signal. The two characteristic frequencies form independently of one another and can, advantageously, be ascertained simultaneously.

In contrast to the prior art, in which a cyclic detection of the entire ODMR spectrum is carried out with only one measurement channel, a multi-channel measurement operation is provided in the case of the present invention. While, in single-channel measurement operation, information about the magnetic flux density can be provided only discontinuously, the present invention allows the simultaneous and continuous detection of relevant information from the ODMR spectrum, in particular the detection of the two minima in the fluorescence signal. In this way, the effort with regard to the detection of the fluorescence minima can be reduced considerably.

The excitation unit for optical excitation of the defect can, for example, be a laser or a light-emitting diode (LED). The detector may in turn be, for example, a photodetector or a CMOS sensor. In addition, the detection unit can have further optical elements—for example, different filters, lenses, or mirrors. The excitation unit and the detector can be arranged, on the one hand, in the region of the crystal body, or can be spatially separated from the crystal body. In addition, an optical fiber arrangement with at least one optical fiber can be present, which optical fiber arrangement can be arranged and/or configured in such a way that the excitation light is guided from the excitation unit to the crystal body and/or the fluorescence signal from the crystal body to the detector.

In one embodiment, the statement about the magnetic field concerns the magnetic permeability, the magnetic susceptibility, or the magnetic flux density.

In a further embodiment, the excitation unit comprises a device, in particular a voltage-controlled oscillator, for producing at least one excitation signal. In addition, the excitation unit can have a control unit for regulating at least the first excitation frequency.

A further embodiment of the detection unit includes that the evaluation unit comprise a computing unit in which at least one, in particular, multi-variable, algorithm, and, in particular, a variation algorithm, a regression algorithm, or an, in particular, adaptive, multi-parameter-fit algorithm, is stored for determining the first excitation frequency and/or the second excitation frequency on the basis of the fluorescence signal.

In particular, the algorithm can also be a self-teaching algorithm. The algorithm is preferably designed to ascertain the first excitation frequency and/or the second excitation frequency on the basis of a correlated variation. In this case, the first excitation frequency and/or the second excitation frequency are determined such that the first local minimum and/or the second local minimum occur in the fluorescence signal at the first excitation frequency and/or at the second excitation frequency.

In this regard, it is advantageous if the excitation unit comprises a first device for producing the first excitation signal and a second excitation unit comprises a device for producing the second excitation signal, which devices are controlled by means of a correlated variation of at least one parameter of the devices and an adaptive, multi-parameter fitting method such that the fluorescence signal has a minimum.

One embodiment of the detection unit includes that the evaluation unit, in particular the computing unit, be configured to determine a local or global extreme value, in particular a minimum of an integral intensity of the fluorescence signal, and to ascertain the first excitation frequency and/or the second excitation frequency on the basis of the extreme value.

In a further embodiment, the evaluation unit is configured to produce at least one modulation excitation signal having a specifiable modulation excitation frequency, which is superimposed on the first excitation signal and/or the second excitation signal. On the basis of the modulation signal, the first excitation signal and the second excitation signal can be distinguished from one another, for example. Advantageously, the frequency of the modulation excitation signal is low compared to the frequency of the respective excitation signal.

It is advantageous if the evaluation unit, in particular a computing unit, is configured to determine the modulation excitation frequency in such a way that it is proportional to the difference between the first excitation frequency and the second excitation frequency. In this case, a suitable algorithm is stored in the computing unit. In particular, the modulation frequency is varied such that the fluorescence signal has an extreme value, and in particular a minimum.

In this context, it is also advantageous if the excitation unit comprises a mixing unit, in particular a multiplier, wherein the excitation unit is configured to produce a base excitation signal having a base excitation frequency and a modulation excitation signal having a modulation excitation frequency, and to produce the first excitation signal and the second excitation signal in such a way that the first excitation frequency is formed from a sum of the base excitation frequency and the modulation frequency, and the second excitation frequency is formed from a difference between the base excitation frequency and the modulation frequency. The base excitation frequency is accordingly a center frequency, which is arranged centrally between the first excitation frequency and the second excitation frequency. Preferably, the base excitation signal and the modulation frequency are varied such that the fluorescence signal has an extreme value, and in particular a minimum.

A further embodiment of the detection unit includes that the excitation unit have a first device for producing the first excitation signal having the first specifiable excitation frequency and a second device for producing the second excitation signal having the second specifiable excitation frequency. In this context, two control units can also be present for setting the first excitation frequency and the second excitation frequency.

It is advantageous if the evaluation unit is configured to produce a first modulation excitation signal having a first specifiable modulation excitation frequency for modulating the first excitation signal and a second modulation excitation signal having a second specifiable modulation excitation frequency for modulating the second excitation signal.

It is also advantageous if the evaluation unit is configured to detect the first excitation frequency and the second excitation frequency on the basis of the first modulation excitation frequency and the second modulation excitation frequency.

It is also possible to carry out an, in particular, low-frequency modulation of the first excitation signal and/or of the second excitation signal or of the base excitation signal to avoid interference effects.

The object of the invention is further achieved by a magnetic sensor for detecting a magnetic field, comprising a detection unit in accordance with the invention according to at least one of the described embodiments.

The object of the invention is also achieved by a sensor device for determining and/or monitoring a process variable and/or characteristic variable of a medium in a container, comprising
a crystal body with at least one defect,
a magnetic field device for producing a magnetic field,
   wherein the magnetic field device is arranged such that a magnetic field in the region of the crystal body and in the region of the medium located inside the container can be produced by means of the magnetic field device, and
a detection unit in accordance with the invention according to at least one of the described embodiments,
   wherein the sensor device is configured to ascertain at least one statement about the process variable on the basis of the statement about the magnetic field.

With regard to the sensor device, it is advantageous if the crystal body is a diamond having at least one silicon or nitrogen defect, is silicon carbide having at least one silicon defect, or is hexagonal boron nitride having at least one defect color center.

Finally, the object of the invention is achieved by a method for detecting a magnetic field by means of a magnetic sensor using a crystal body having at least one defect, comprising the following method steps:
optically exciting the defect of the crystal body by means of an excitation light,
producing high-frequency radiation or microwave radiation in the region of the crystal body by means of a first excitation signal having at least a first specifiable excitation frequency and a second excitation signal having a second specifiable excitation frequency,
detecting a magnetic-field-dependent fluorescence signal from the crystal body,
determining the first excitation frequency and/or the second excitation frequency of the first excitation signal and/or the second excitation signal on the basis of the fluorescence signal such that the fluorescence signal as a function of the frequency has a minimum at the first excitation frequency and/or at the second excitation frequency, and
ascertaining a statement about the magnetic field on the basis of the first excitation frequency and/or the second excitation frequency.

The embodiments described in connection with the detection unit according to the invention are applicable mutatis mutandis for the magnetic sensor according to the invention, the sensor arrangement according to the invention, and the method according to the invention, and vice versa.

The invention and its advantageous embodiments are explained in more detail with reference to the following figures. In the figures:

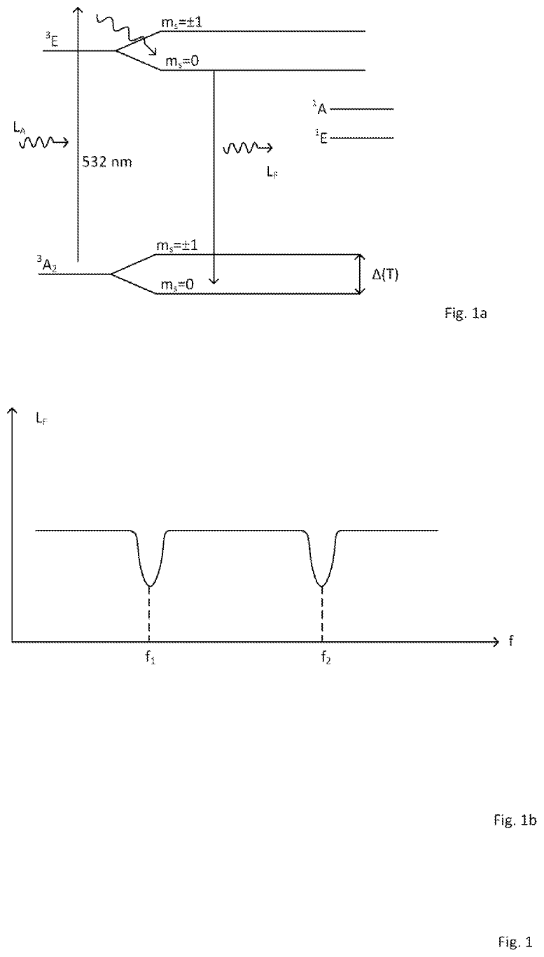

FIG. 1: shows (a) a simplified energy scheme for a negatively-charged NV center in diamond and (b) the fluorescence signal as a function of the frequency;

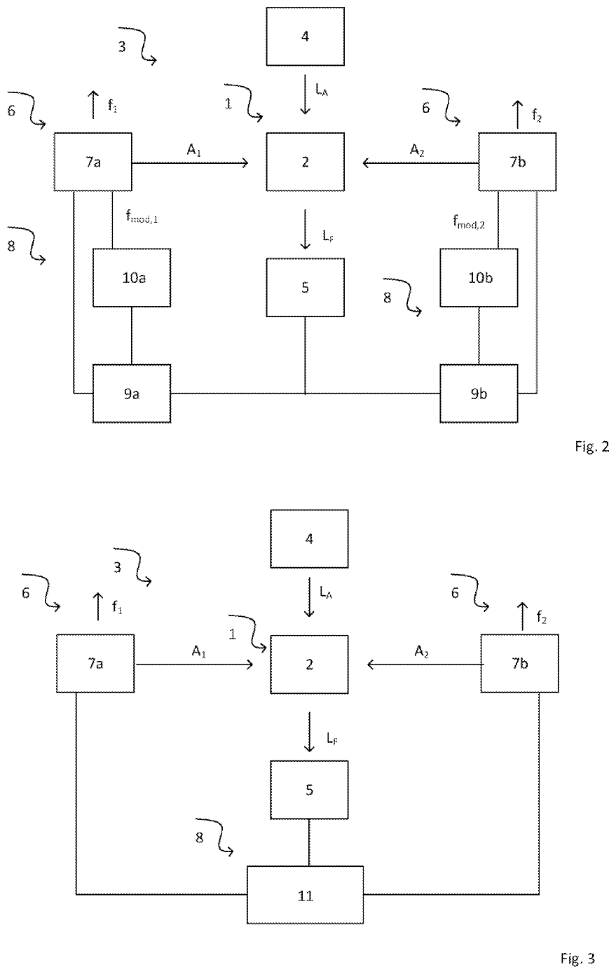

FIG. 2: shows a first embodiment of a detection unit according to the invention,

FIG. 3: shows a second embodiment of a detection unit according to the invention,

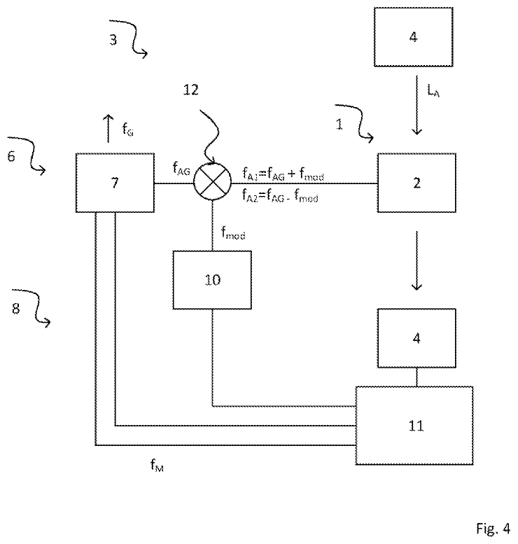

FIG. 4: shows a third embodiment of a detection unit according to the invention, and

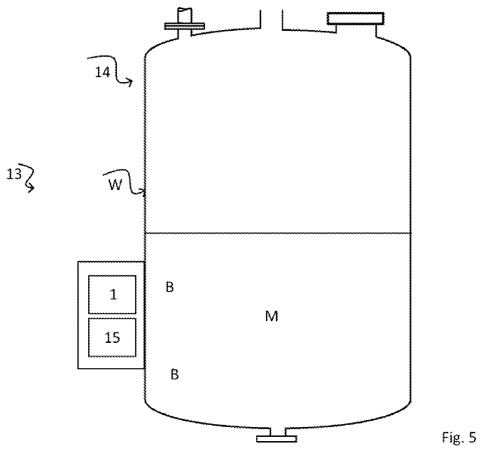

FIG. 5: shows an exemplary sensor device according to the invention.

In the figures, identical elements are provided with the same reference signs.

In FIG. 1a, a simplified energy diagram for a negatively-charged NV center in diamond is shown. In this way, the excitation of the defect and the detection of fluorescence can be explained by way of example. The following considerations apply equally to other crystal bodies having corresponding defects.

In diamond, each carbon atom is typically covalently bonded to four further carbon atoms. A nitrogen vacancy center (NV center) consists of a vacancy in the diamond lattice, i.e. an unoccupied lattice site, and a nitrogen atom as one of the four neighboring atoms. In particular, the negatively-charged NV⁻ centers are important for the excitation and evaluation of fluorescence signals. In the energy diagram of a negatively-charged NV center, there is a triplet ground state ³A and an excited triplet state ³E, each of which has three magnetic substrates mₛ=0,±1. Furthermore, there are two metastable singlet states ¹A and ¹E between the ground state ³A and the excited state ³E. In the absence of an external magnetic field, a splitting of the two states mₛ=+/−1 from the ground state mₛ=0 occurs, which is referred to as zero field splitting Δ and which is dependent upon the temperature T.

Excitation light L_{A} from the green range of the visible spectrum, e.g., an excitation light L_{A} having a wavelength of 532 nm, excites an electron from the ground state ³A into a vibrational state of the excited state ³E, which returns to the ground state ³A by emitting a fluorescence photon L_{F} having a wavelength of 630 nm.

An additional applied magnetic field with a magnetic field strength B leads to a splitting (Zeeman splitting) of the magnetic sub-states, so that the ground state consists of three, energetically-separated sub-states, each of which can be excited. The intensity of the fluorescence signal L_{F} is dependent upon the respective magnetic sub-state from which it was excited, so that the magnetic flux density B can be determined on the basis of, for example, the distance between the fluorescence minima. The equation Δf=f₂−f₁˜γB applies, where γ is the gyromagnetic ratio, and B is the magnetic flux density.

In FIG. 1b, the fluorescence signal L_{F} is illustrated as a function of the frequency f. The fluorescence signal L_{F} has a minimum at the two characteristic frequencies f₁ and f₂. These two frequencies f₁ and f₂ correspond to the energetic position of electron spin resonances. Accordingly, from the two frequencies f₁ and f₂, a statement about the magnetic field can be obtained, e.g., the magnetic flux density, the magnetic permeability, or the magnetic susceptibility.

The present invention provides a multi-channel, simultaneous determination of the first frequency f₁ and the second frequency f₂, wherein the frequencies can be detected continuously. In this connection, various embodiments for a detection unit according to the invention are possible, of which three preferred variants are explained in more detail below.

FIG. 2 shows a first possible embodiment of a detection unit 3 according to the invention for a magnetic sensor 1 with a crystal body 2 having at least one defect. The crystal body 2 is irradiated by means of the light source 4 with an excitation light L_{A}, and a fluorescence signal L_{F} of the crystal body 2 is detected by means of the detector 5.

In addition, the detection unit 3 comprises an excitation unit 6 for radiating high-frequency radiation or microwave radiation with two devices 7a and 7b for producing the first excitation signal A₁ and the second excitation signal A₂ in the form of two, voltage-controlled oscillators and an evaluation unit 8.

The evaluation unit 8 is designed, on the basis of the fluorescence signal L_{F}, to produce the first excitation frequency f₁ and the second excitation frequency f₂ in such a way that, for the first excitation frequency f₁ and the second excitation frequency f₂, the fluorescence signal L_{F} has a minimum in each case. The evaluation unit 8 from FIG. 2 comprises, by way of example, a first lock-in 9a and a second lock-in 9b, which serve for controlling the first excitation frequency f₁ and the second excitation frequency f₂ such that, at the two frequencies f₁ and f₂, the minimum in the fluorescence signal L_{F} occurs in each case. Preferably, the first lock-in 9a and the second lock-in 9b can be controlled in parallel to each other.

In addition, the evaluation unit 8 can also be one or two control units (not shown here) for regulating the first frequency f₁ and/or the second frequency f₂. In addition to the evaluation unit shown here with the first lock-in 9a and the second lock-in 9b, numerous further embodiments are provided for the evaluation unit 8, in particular for the variation and/or control of the frequencies f₁, f₂ of the excitation signals A₁, A₂, which also fall under the present invention.

The evaluation unit further comprises two modulation units 10a and 10b for producing a first modulation signal A_{mod,1} and a second modulation signal A_{mod,2}, having a first modulation frequency f_{mod,1} and a second modulation frequency f_{mod,2}, by means of which modulation signals A_{mod,1}, A_{mod,2} the first excitation signal A₁ and the second excitation signal A₂ are modulated. On the basis of the two modulation signals A_{mod,1}, A_{mod,2}, the first excitation frequency f₁ and the second excitation frequency f₂ can be distinguished from one another in continuous operation. Preferably, the two modulation signals A_{mod,1}, A_{mod,2} are different, and in particular have different frequencies f_{mod,1}, f_{mod,2}.

The detection unit 8 allows the simultaneous and independent control of the first excitation signal A₁ and the second excitation signal A₂ or an independent determination of the two frequencies f₁ and f₂, which serve for ascertaining a statement about the magnetic field. Preferably, the two voltage-controlled oscillators 7a and 7b are operated in two different, non-overlapping frequency ranges.

Advantageously, by selecting different frequency ranges for the two voltage-controlled oscillators 7a and 7b and/or by selecting different modulation frequencies f_{mod,1}, f_{mod,2} for the two modulation signals A_{mod,1}, A_{mod,2}, a mutual influence of the two measurement channels for determining the first frequency f₁ and the second frequency f₂ can be excluded. Both frequencies f₁ and f₂ can be determined simultaneously and continuously, in particular in the regulated state of the system.

A second preferred embodiment of a detection unit 3 according to the invention is the subject matter of FIG. 3. In the case of FIG. 3, the evaluation unit 8 comprises a computing unit 11 in which at least one algorithm is stored for ascertaining the first excitation frequency f₁ and/or the second excitation frequency f₂ on the basis of the fluorescence signal L_{F}. In this embodiment, the computing unit 11 thus in principle takes over the tasks of the first and second lock-ins 9a, 9b and the task of the two modulation units 10a and 10b from FIG. 2. In particular, the algorithm is configured to use a global minimum of an integral intensity of the fluorescence signal L_{F} to determine the first frequency f₁ and the second frequency f₂. In this case, the evaluation unit 8 can also further be connected via two control units (likewise not shown separately here) to the, in particular, correlated variation of the two frequencies f₁, f₂.

A third preferred embodiment of a detection unit 3 according to the invention is shown in FIG. 4. The excitation unit 6 comprises a device 7 for producing at least one excitation signal A in the form of a voltage-controlled oscillator or the like and a mixing unit 12—in this case, in the form of a multiplier.

By means of the voltage-controlled oscillator 7, a base excitation signal A_{G} having a base excitation frequency f_{AG} is produced. By means of the modulation unit 10, a modulation excitation signal A_{mod} is in turn produced with a modulation excitation frequency f_{mod}, The base excitation frequency f_{AG} and the modulation frequency f_{mod} are determined by means of a suitable algorithm stored in the computing unit 11 such that an integral intensity of the fluorescence signal L_{F} has a global minimum.

The first excitation signal A₁ or the second excitation signal A₂ result in this case from a sum or difference of the base excitation frequency fc and the modulation frequency f_{mod}, In this case, the equation Δf=2f_{mod} results. From the base excitation frequency f_{AG}, a statement about a temperature in the region of the crystal body 2 can, further optionally, be obtained, in particular on the basis of the zero-field splitting of the ground state.

Moreover, for the embodiment from FIG. 4, an optional additional modulation having a low-frequency modulation frequency f_{M} for reducing interference effects is implemented.

FIG. 5, finally, shows a sensor arrangement 13 according to the invention which serves for the determination and/or monitoring of a process variable and/or characteristic variable of a medium M in a container 14. The sensor arrangement 13 comprises a magnetic sensor 1 according to the invention, a magnetic field device 15 for producing a magnetic field (shown here on the basis of the magnetic flux density B), which penetrates the crystal body 2 of the magnetic sensor 1 and at least a part of the medium M, and a detection unit 3 according to the invention. A change in the process variable and/or characteristic variable of the medium leads here, for example, to a change in the magnetic field B which can be detected by means of the magnetic sensor 1, which comprises a detection unit 3 according to the invention. Numerous different embodiments are conceivable of the sensor device 13 according to the invention.

### LIST OF REFERENCE SIGNS

1 Magnetic sensor
2 Crystal body with defect
3 Detection unit
4 Light source
5 Detector
6 Excitation unit
7 (a, b) Device for producing the excitation signal
8 Evaluation unit
9 (a, b) Lock-in
10 (a, b) Modulation unit
11 Computing unit
12 Mixer
13 Sensor device
14 Container
15 Magnetic field device
M Medium
W Wall
L_{A} Excitation light
L_{F} Fluorescent light
f Frequency
f₁ First frequency
f₂ Second frequency
f_{G} Base frequency
A₁ First excitation signal
A₂ Second excitation signal
A_{G} Base excitation signal
f_{mod,1} First modulation signal
f_{mod,2} Second modulation signal
f_{M} Additional modulation
B Magnetic field or magnetic flux density
γ Gyromagnetic ratio

1-15. (canceled)

16. A detection unit for a magnetic sensor for detecting a magnetic field via a crystal body having at least one defect, the detection unit comprising:
a light source for optical excitation of the at least one defect in the crystal body with an excitation light;
an excitation unit for producing a high-frequency radiation in a region of the crystal body, wherein the excitation unit is designed to produce a first excitation signal having a first specifiable excitation frequency and a second excitation signal having a second specifiable excitation frequency;
a detector of a magnetic-field-dependent fluorescence signal from the crystal body; and
an evaluation unit which is designed to:
ascertain the first excitation frequency of the first excitation signal and the second excitation frequency of the second excitation signal on the basis of the fluorescence signal such that the fluorescence signal as a function of the frequency has a minimum at the first excitation frequency and/or at the second excitation frequency, and
ascertain a statement about the magnetic field on the basis of the first excitation frequency and/or the second excitation frequency.

17. The detection unit according to claim 16,
wherein the statement about the magnetic field is a magnetic permeability, a magnetic susceptibility, or a magnetic flux density.

18. The detection unit according to claim 16,
wherein the excitation unit includes a device for producing at least one excitation signal.

19. The detection unit according to claim 16,
wherein the evaluation unit includes a computing unit in which at least one algorithm for determining the first excitation frequency and/or the second excitation frequency on the basis of the fluorescence signal is stored.

20. The detection unit according to claim 19,
wherein the evaluation unit is configured to ascertain an extreme value of an integral intensity of the fluorescence signal and to ascertain the first excitation frequency and/or the second excitation frequency on the basis of the extreme value.

21. The detection unit according to claim 16,
wherein the evaluation unit is configured to produce at least one modulation excitation signal having a specifiable modulation excitation frequency which can be superimposed on the first excitation signal and/or the second excitation signal.

22. The detection unit according to claim 21,
wherein the evaluation unit is configured to ascertain the modulation excitation frequency so that it is proportional to the difference between the first excitation frequency and the second excitation frequency.

23. The detection unit according to claim 22,
wherein the excitation unit includes a mixing unit, and
wherein the excitation unit is designed to:
produce a base excitation signal having a base excitation frequency and a modulation excitation signal having a modulation excitation frequency, and
produce the first second excitation signal and the second excitation signal such that the first excitation frequency is formed from a sum of the base excitation frequency and the modulation frequency, and the second excitation frequency is formed from a difference between the base excitation frequency and the modulation frequency.

24. The detection unit according to claim 16,
wherein the excitation unit has a first device for producing the first excitation signal having the first specifiable excitation frequency and a second device for producing the second excitation signal having the second specifiable excitation frequency.

25. The detection unit according to claim 24,
wherein the evaluation unit is configured to produce a first modulation excitation signal having a first specifiable modulation excitation frequency for modulating the first excitation signal and a second modulation excitation signal having a second specifiable modulation excitation frequency for modulating the second excitation signal.

26. The detection unit according to claim 25,
wherein the evaluation unit is configured to detect the first excitation frequency and the second excitation frequency on the basis of the first modulation excitation frequency and the second modulation excitation frequency.

27. A magnetic sensor for detecting a magnetic field, comprising:
a detection unit for a magnetic sensor for detecting a magnetic field via a crystal body having at least one defect, the detection unit including:
a light source for optical excitation of the at least one defect in the crystal body with an excitation light;
an excitation unit for producing a high-frequency radiation in a region of the crystal body, wherein the excitation unit is designed to produce a first excitation signal having a first specifiable excitation frequency and a second excitation signal having a second specifiable excitation frequency;
a detector of a magnetic-field-dependent fluorescence signal from the crystal body; and
an evaluation unit which is designed to:
ascertain the first excitation frequency of the first excitation signal and the second excitation frequency of the second excitation signal on the basis of the fluorescence signal such that the fluorescence signal as a function of the frequency has a minimum at the first excitation frequency and/or at the second excitation frequency, and
ascertain a statement about the magnetic field on the basis of the first excitation frequency and/or the second excitation frequency.

28. A sensor device for determining and/or monitoring a process variable and/or a characteristic variable of a medium in a container, the sensor device comprising:
a crystal body having at least one defect;
a magnetic field device for producing a magnetic field, wherein the magnetic field device is arranged such that a magnetic field can be produced in a region of the crystal body and in a region of the medium located inside the container; and
a detection unit for a magnetic sensor for detecting the magnetic field via the crystal body, the detection unit including:
a light source for optical excitation of the at least one defect in the crystal body with an excitation light;
an excitation unit for producing a high-frequency radiation in a region of the crystal body, wherein the excitation unit is designed to produce a first excitation signal having a first specifiable excitation frequency and a second excitation signal having a second specifiable excitation frequency;
a detector of a magnetic-field-dependent fluorescence signal from the crystal body; and
an evaluation unit which is designed to:
ascertain the first excitation frequency of the first excitation signal and the second excitation frequency of the second excitation signal on the basis of the fluorescence signal such that the fluorescence signal as a function of the frequency has a minimum at the first excitation frequency and/or at the second excitation frequency, and
ascertain a statement about the magnetic field on the basis of the first excitation frequency and/or the second excitation frequency,
wherein the sensor device is configured to ascertain at least one statement about the process variable on the basis of the statement about the magnetic field.

29. The sensor device according to claim 28,
wherein the crystal body is a diamond having at least one silicon or nitrogen defect, is silicon carbide having at least one silicon defect, or is hexagonal boron nitride having at least one defect color center.

30. A method for detecting a magnetic field using a magnetic sensor with a crystal body having at least one defect, the method comprising:
optically exciting the at least one defect of the crystal body with an excitation light;
producing high-frequency radiation in a region of the crystal body via a first excitation signal having a first specifiable excitation frequency and a second excitation signal having a second specifiable excitation frequency;
detecting a magnetic-field-dependent fluorescence signal from the crystal body;
determining the first excitation frequency and/or the second excitation frequency of the first excitation signal and/or of the second excitation signal on the basis of the fluorescence signal such that the fluorescence signal as a function of the frequency has a minimum at the first excitation frequency and/or at the second excitation frequency; and
ascertaining a statement about the magnetic field on the basis of the first excitation frequency and/or the second excitation frequency.
